(19) United States
(12) Patent Application Publication
(10) Pub. No.: US 2006/0156988 A1
(43) Pub. Date: Jul. 20, 2006

(54) Pin set for a reactor

(75) Inventors: Chia-Te Wu, Ping Chen City (TW); Te-Tsai Cheng, Taoyuan Hsien (TW); Shen-You Yeh, Ping Chen City (TW)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: Chunghwa Picture TUbes, Ltd.

(21) Appl. No.: 11/085,403

(22) Filed: Mar. 21, 2005

(30) Foreign Application Priority Data
Jan. 14, 2005 (TW) 94101231

(51) Int. Cl. C23C 16/00

(52) U.S. Cl. 118/728

(57) ABSTRACT

A pin set is provided for a reactor, and the pin set has a lift pin, a pin guide and a pin weight. The pin guide is configured in the reactor and has a guide hole for the lift pin to move through. A guide gap is positioned between the guide hole and the lift pin. The pin weight has a weight hole, and a first end of the lift pin passes through the weight hole and is fixed on the pin weight. A weight gap is positioned between the weight hole and the lift pin, and the weight gap is smaller than the guide gap.

### RELATED APPLICATIONS

The present application is based on, and claims priority from, Taiwan Application Serial Number 94101231, filed on Jan. 14, 2005, the disclosure of which is hereby incorporated by reference herein in its entirety.

### BACKGROUND

1. Field of Invention

The present invention relates to an apparatus for manufacturing a semiconductor device. More particularly, the present invention relates to a pin set for a reactor.

2. Description of Related Art

In order to decrease costs, the conventional manufacturing of liquid crystal display panels generally forms multiple panels on a large-sized substrate simultaneously, and then cuts the substrate into individual panels after the whole manufacturing is nearly complete. During the manufacturing, the large-sized substrate is transferred to different reactors for different processes according to the required processing stages. By the lifting and lowering of lift pins, the reactor transfers the substrate delivered by a mechanical arm to a surface of a substrate support inside the reactor for performing a deposition, etching, polishing or edging process.

FIG. 1A and FIG. 1B are schematic views of a conventional pin set, wherein the pin set in FIG. 1A is at a lifting position, and the pin set in FIG. 1B is at a lowering position. The pin set has a lift pin 102, a pin guide 104 and a pin weight 106. The pin guide 104 is fixed on a substrate support 108 of the reactor. One end of the lift pin 102 passes through the pin guide 104, and the moving direction of the lift pin 102 is guided by the pin guide 104. The other end of the lift pin 102 is fixed on the pin weight 106 by using a C-type retaining ring 126. When requiring the lift pin 102 to move upward, an elevating device 110 moves upward to elevate the lift pin 102 (as illustrated in FIG. 1A); when requiring the lift pin 102 to move downward, the elevating device 110 moves downward first, and the lift pin 102 then falls due to the pin weight 106 and the gravity thereof (as illustrated in FIG. 1B).

Generally, a chemical vapor deposition reactor used for the film deposition process of a panel is a high-temperature device (about 280° C.). A substrate (such as a glass substrate) is deformed under such a high temperature. FIG. 2 is a schematic view of the conventional pin set which supports a deformed substrate, where the substrate 200 is deformed due to being heated. As illustrated in FIG. 2, when the substrate 200 is transferred to the surface of the substrate support 108 by a mechanical arm, the deformed substrate 200 applies a lateral force to the lift pin 102.

In the traditional design, the lift pin 102 loosely fits the pin weight 106, and the gap therebetween (about 0.1 mm) is greater than a gap (about 0.05 mm) between the lift pin 102 and the pin guide 104. By the traditional design, when a force is applied to the lift pin 102, a pivot for the lift pin 102 is located on the pin guide 104, and the lift pin 102 is therefore skewed and unable to smoothly move upward or downward.

More specifically, if the pin weight 106 is not heavy enough, the skewed lift pin 102 will get stuck and not fall down, and the substrate 200 thus will not be correctly positioned. The incorrectly positioned substrate 200 will crack the wall of the reactor if the mechanical arm takes the substrate 200 at this moment and will cause broken pieces. Besides polluting the reactor inside, the cracking reduces the manufacturing throughput because of the need to clean the broken pieces. Moreover, when the film deposition is performed with plasma, the incorrectly positioned substrate 200 causes abnormal film quality or film thickness and decreases the yield because of the uneven plasma distribution on its surface.

In another aspect, if the pin weight 106 is heavy enough, the foregoing skewed lift pin 102 will be forced to fall down. The forced falling causes wear of the lift pin 102 and the pin guide 104, which not only substantially reduces the lifetimes of both, but also decreases the yield because the debris generated by wearing pollutes the reactor inside.

### SUMMARY

It is therefore an aspect of the present invention to provide a pin set, of which the pivot of the lift pin is changed to solve the seizing up or wearing of the lift pin as mentioned above.

It is another aspect of the present invention to provide a pin set for a reactor, which makes its lift pin move smoothly in order to extend the lifetime of the pin set and mitigate the particle pollution caused by wearing.

It is yet another aspect of the present invention to provide a reactor, which changes the relative relationships of the gaps between the lift pin, the pin guide and the pin weight, for decreasing the broken substrate pieces, improving the film quality and the uniformity of the film thickness, and further increasing the manufacturing throughput and raising the yield of products.

According to one preferred embodiment of the present invention, a pin set is provided for a reactor, and the pin set has a lift pin, a pin guide and a pin weight. The pin guide is configured in the reactor and has a guide hole for the lift pin to move through. A guide gap is positioned between the guide hole and the lift pin. The pin weight has a weight hole, where a first end of the lift pin passes through the weight hole and is fixed on the pin weight. A weight gap is positioned between the weight hole and the lift pin, and the weight gap is smaller than the guide gap.

It is to be understood that both the foregoing general description and the following detailed description are examples and are intended to provide further explanation of the invention as claimed.

### BRIEF DESCRIPTION OF THE DRAWINGS

These and other features, aspects, and advantages of the present invention will become better understood with regard to the following description, appended claims, and accompanying drawings where:

FIG. 1A and FIG. 1B are schematic views of a conventional pin set, wherein the pin set in FIG. 1A is at a lifting position, and the pin set in FIG. 1B is at a lowering position;

FIG. 2 is a schematic view of the conventional pin set which supports a deformed substrate; and

FIG. 3 is a schematic view of one preferred embodiment of the present invention.

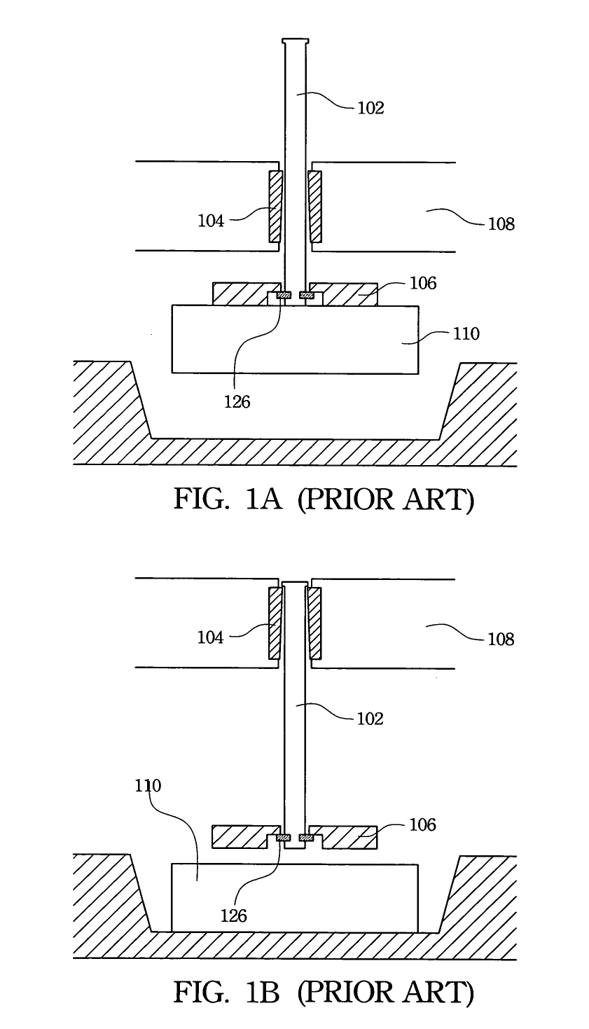

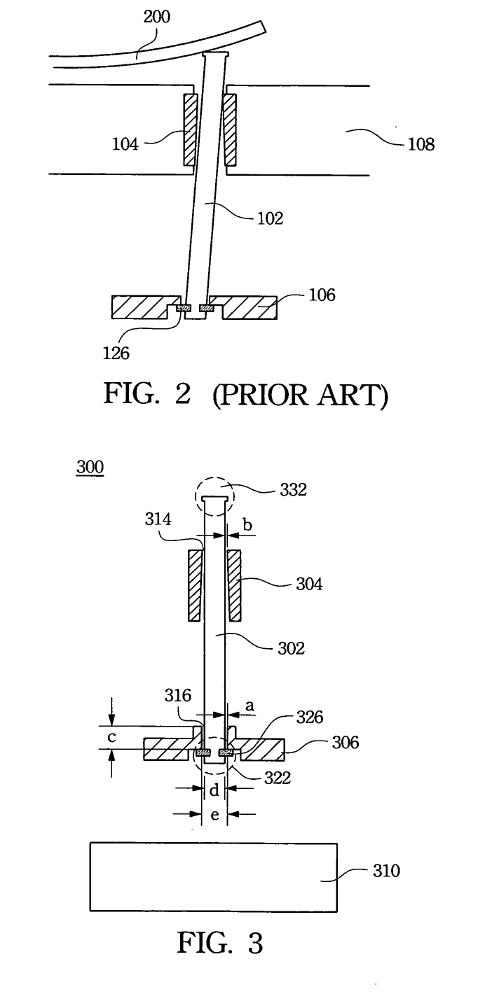

### DESCRIPTION OF THE PREFERRED EMBODIMENTS

Reference will now be made in detail to the present preferred embodiments of the invention, examples of which are illustrated in the accompanying drawings. Wherever possible, the same reference numbers are used in the drawings and the description to refer to the same or like parts.

FIG. 3 is a schematic view of one preferred embodiment of the present invention. A pin set 300 is provided for a reactor, which helps the substrate transfer between a mechanical arm and a surface of a substrate support by lifting and lowering its lift pin. The reactor is used to perform deposition, etching, polishing or edging processes, such as in a chemical vapor deposition reactor for the film deposition of panels.

First of all, some designations are defined for clear description. A weight gap positioned between the weight hole and the lift pin is designated as ‘a’, a guide gap positioned between the guide hole and the lift pin is designated as ‘b’, a length of a contact surface of the lift pin inside the weight hole is designated as ‘c’, a size of the weight hole is designated as ‘e’, and a size of a first end of the lift pin is designated as ‘d’.

As illustrated in FIG. 3, the pin set 300 has a lift pin 302, a pin guide 304 and a pin weight 306. The pin guide 304 is configured inside the reactor, such as being fixed in a substrate support of the reactor (not illustrated). The pin guide 304 has a guide hole 314. The lift pin 302 passes through the guide hole 314 and moves upward and downward inside with the guidance of its moving directed by the pin guide 304. Moreover, a guide gap b is positioned between the guide hole 314 and the lift pin 302. The pin weight 306 has a weight hole 316. A first end 322 of the lift pin 302 passes through the weight hole 316 and is fixed on the pin weight 306. A weight gap a is positioned between the weight hole 316 and the lift pin 302.

In the preferred embodiment, the gap between the lift pin 302 and the pin weight 306 is shrunk to be smaller than the gap between the lift pin 302 and the pin guide 304 such that the pivot is changed when a lateral force is applied to the lift pin 302 by the substrate. More particularly, the weight gap a positioned between the weight hole 316 and the lift pin 302 is smaller than the guide gap b positioned between the guide hole 314 and the lift pin 302. Therefore, when the substrate applies a lateral force to a second end 332 of the lift pin 302 and thus generates a moment, the lift pin 302 will use the pin weight to be its pivot according to the foregoing relative relationship between the two gaps a and b, not the pin guide as in the conventional design.

Moreover, the preferred embodiment also provides several better conditions of design to further improve the performance of the pin set 300. For example, the weight gap a is smaller than the guide gap b by more than 0.01 mm, and this prevents the lift pin 302 from getting stuck within the pin guide 304 and causing wearing. A length c of a contact surface of the lift pin 302 inside the weight hole 316 is not smaller than 3 mm. The contact surface between the lift pin 302 and the pin weight 306 is increased to protect the lift pin 302 from breaking due to insufficient contacting strength. The size e of the weight hole 316 is greater than the size d of the first end 322 of the lift pin 302 by more than 0.05 mm, thus preventing the incapable movement due to the seizing of the lift pin 302 on the pin weight 306.

Furthermore, the second end 332 of the lift pin 302 supports the substrate. The size of the second end 332 is greater in diameter than the guide hole 314 to prevent the lift pin 302 from totally dropping through the pin guide 304. The first end 322 of the lift pin 302 is fixed on the pin weight 306 by a retaining ring (such as a C-type retaining ring or other type of retaining ring). The pin set 300 further comprises an elevating device 310 to drive the elevating of the lift pin 302. When requiring the lift pin 302 to move upward, an elevating device 310 moves upward to elevate the lift pin 302; when requiring the lift pin 302 to move downward, the elevating device 310 moves downward first, and the lift pin 302 then falls due to the pin weight 306 and the gravity thereof.

By the foregoing designs, the lift pin 302 of the preferred embodiment can move upward and downward smoothly, and thus the lifetime thereof is extended and the particle pollution caused by wearing is mitigated. Table 1 below is used to compare the conventional pin set and the pin set of the preferred embodiment and separately lists the liquid crystal cell defect yield, the broken pieces and the work-in pieces of both, to show that the preferred embodiment certainly solves the problems of the conventional pin set.

TABLE 1
A comparison between the pin sets of the conventional design
and the preferred embodiment.

| | Liquid crystal cell defect | Broken piece | Work-in piece |
|---|---|---|---|
| | yield (%) | (pieces) | (pieces) |
| Conventional | 1.34 | 5 | 200 |
| design | | | |
| Preferred | 0.05 | 0 | 60 |
| embodiment | | | |

As seen in Table 1, the preferred embodiment mitigates the abnormalities of the film quality and the film thickness of the substrate such that the liquid crystal cell defect yield is reduced from 1.34% to 0.05%. The quantity of the broken pieces caused by the skewed lift pin also is decreased from 5 pieces to none. Moreover, cleaning broken pieces is not needed anymore, and therefore the quantity of the work-in piece is decreased from 200 pieces to 60 pieces, substantially increasing the capacity. In other words, by using the pin set of the preferred embodiment, the broken substrate pieces inside the reactor can be substantially decreased and the film quality and thickness of the substrate can be improved, thus further increasing the manufacturing throughout and enhancing the yield of products.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A pin set provided for a reactor, the pin set comprising:
a lift pin;
a pin guide, configured in the reactor, the pin guide having a guide hole for the lift pin to move through, and a guide gap being positioned between the guide hole and the lift pin; and
a pin weight, having a weight hole, a first end of the lift pin passing through the weight hole and being fixed on the pin weight, and a weight gap being positioned between the weight hole and the lift pin, wherein the weight gap is smaller than the guide gap.

2. The pin set of claim 1, wherein when a substrate produces a moment on the lift pin, a pivot of the moment is located on the pin weight.

3. The pin set of claim 1, wherein a length of a contact surface of the lift pin inside the weight hole is not smaller than 3 mm.

4. The pin set of claim 1, wherein the weight gap is smaller than the guide gap by more than 0.01 mm.

5. The pin set of claim 1, wherein the weight hole is greater than the first end of the lift pin by more than 0.05 mm.

6. The pin set of claim 1, wherein a second end of the lift pin supports a substrate, and the second end is greater in diameter than the guide hole.

7. The pin set of claim 1, wherein the first end is fixed on the pin weight by a retaining ring.

8. The pin set of claim 1, wherein the pin set further comprises an elevating device to drive an elevating of the lift pin.

9. A pin set of a reactor, comprising:
a lift pin;
a pin guide, the lift pin passing through the pin guide, and a guide gap being positioned between the pin guide and the lift pin; and
a pin weight, configured on a first end of the lift pin, a weight gap being positioned between the pin weight and the lift pin, and the weight gap being smaller than the guide gap.

10. The pin set of claim 9, wherein a second end of the lift pin supports a substrate, and when the substrate produces a moment on the lift pin, a pivot of the moment is located on the pin weight.

11. The pin set of claim 9, wherein a length of a contact surface between the lift pin and the pin weight is not smaller than 3 mm.

12. The pin set of claim 9, wherein the weight gap is smaller than the guide gap by more than 0.01 mm.

13. The pin set of claim 9, wherein the lift pin is fixed on the pin weight by a retaining ring.

14. The pin set of claim 9, wherein the pin set further comprises an elevating device to move the lift pin upward and downward.

15. A reactor, having a pin set to move a substrate upward and downward, the pin set comprising a lift pin, a pin guide and a pin weight, the reactor characterized in that:
the pin guide has a guide hole for the lift pin to move through, and a guide gap is positioned between the guide hole and the lift pin; and
the pin weight has a weight hole, an end of the lift pin passes through the weight hole and is fixed on the pin weight, and a weight gap is positioned between the weight hole and the lift pin, wherein the weight gap is smaller than the guide gap.

16. The reactor of claim 15, wherein when the substrate produces a moment on the lift pin, a pivot of the moment is located on the pin weight.

17. The reactor of claim 15, wherein a length of a contact surface of the lift pin inside the weight hole is not smaller than 3 mm.

18. The reactor of claim 15, wherein the weight gap is smaller than the guide gap by more than 0.01 mm.

19. The pin set of claim 15, wherein the weight hole is greater in diameter than the end of the lift pin by more than 0.05 mm.

20. The reactor of claim 15, wherein the end is fixed on the pin weight by a retaining ring.

21. The reactor of claim 15, wherein the pin set further comprises an elevating device to drive an elevating of the lift pin.
